(19) United States
(12) Patent Application Publication
(10) Pub. No.: US 2023/0369507 A1
(43) Pub. Date: Nov. 16, 2023

(54) LOW ROUGHNESS THIN-FILM TRANSISTORS

(71) Applicant: Amorphyx, Incorporated, Corvallis, OR (US)

(72) Inventor: Sean William MUIR, Corvallis, OR (US)

(73) Assignee: Amorphyx, Incorporated, Corvallis, OR (US)

(21) Appl. No.: 18/248,212

(22) PCT Filed: Oct. 6, 2021
(86) PCT No.: PCT/US2021/053815

§ 371 Date: Apr. 6, 2023

Related U.S. Application Data
(60) Provisional application No. 63/089,489, filed on Oct. 8, 2020.

(51) Int. Cl. H01L 29/786; H01L 29/66; H01L 29/49; H01L 29/51

(52) U.S. Cl. CPC H01L 29/78669; H01L 29/7869; H01L 29/66765; H01L 29/66969; H01L 29/4966; H01L 29/517

(57) ABSTRACT

A thin-film transistor includes a gate electrode formed on a non-conducting substrate. A top surface of the gate electrode has an RMS roughness less than 2 nm. A gate insulator having a thickness less than 25 nm is formed on the gate electrode. A semiconductor material having a thickness less than 50 nm is formed on the gate insulator. The smooth top surface of the gate insulator promotes smooth surfaces of the semiconductor material.

### TECHNICAL FIELD

The present disclosure relates to thin-film transistors.

### DESCRIPTION OF THE RELATED ART

Thin-film transistors are typically formed on non-conducting substrates. Thin-film transistors may be formed using processes that are different than traditional CMOS processes. Because thin-film transistors are not bound by some process constraints of traditional CMOS transistors, thin-film transistors can be utilized in various applications in which it may be difficult to utilize traditional CMOS transistors. These applications can include OLED displays and other types of displays. In spite of the various advantages of thin-film transistors, it can still be difficult to achieve desired transistor conduction characteristics within film transistors.

### BRIEF SUMMARY

The present disclosure is directed to a transistor that includes a non-conducting substrate, a gate electrode positioned on the substrate and having top surface with a root mean square roughness less than 3 nm, a gate insulator positioned on the gate electrode and having a thickness less than 25 nm, and a semiconductor material positioned on the gate insulator and having a thickness less than 50 nm.

A method includes forming a gate electrode on a non-conducting substrate. A top surface of the gate electrode has a root mean square roughness less than 3 nm. The method includes forming, on the gate electrode, a gate insulator having a thickness less than 25 nm, and forming, on the gate insulator, a semiconductor material including a channel region having a thickness less than 50 nm.

In one embodiment, a method includes forming, on a non-conducting substrate, an amorphous metal gate electrode having a top surface with a root mean square roughness less than 2 nm and forming, on the metal gate electrode, a gate insulator having a thickness less than 15 nm. The method includes forming, on the gate insulator, a semiconductor material including a transistor channel region. The gate insulator is positioned between the gate electrode and the channel region. The method includes forming source and drain electrodes in contact with the semiconductor material.

### BRIEF DESCRIPTION OF THE SEVERAL VIEWS OF THE DRAWINGS

The detailed description is described with reference to the accompanying figures. The sizes and relative positions of elements in the figures are not necessarily drawn to scale. For example, the shapes of various elements and angles are not drawn to scale and some of these elements are enlarged and positioned to improve figure legibility. As is understood by one of skill in the art, the shape of a particular element may be modified (e.g., rounded, thinned, elongated, etc.) to suit a particular application.

FIG. 1A-1I are cross-sectional views of a microelectronic device at various stages of formation of a thin-film transistor, according to one embodiment.

FIG. 1J is a top view of the microelectronic device of FIG. 1I, according to one embodiment.

FIG. 2A is a cross-sectional view of a microelectronic device including a thin-film transistor, according to one embodiment.

FIG. 2B is a top view of the microelectronic device of FIG. 2A, according to one embodiment.

FIG. 3A is a cross-sectional view of a microelectronic device including a thin-film transistor, according to one embodiment.

FIG. 3B is a top view of the microelectronic device of FIG. 2A, according to one embodiment.

FIG. 4A is a cross-sectional view of a microelectronic device including a thin-film transistor, according to one embodiment.

FIG. 4B is a top view of the microelectronic device of FIG. 2A, according to one embodiment.

FIG. 5 is a flow diagram of a method for forming a thin-film transistor, according to one embodiment.

FIG. 6 is a flow diagram of a method for forming a thin-film transistor, according to one embodiment.

### DETAILED DESCRIPTION

It will be appreciated that, although specific embodiments of the present disclosure are described for purposes of illustration, various modifications may be made without departing from the spirit and scope of the present disclosure.

In this description, certain specific details are set forth in order to provide a thorough understanding of various aspects of the disclosed subject matter. However, the disclosed subject matter may be practiced without these specific details. In some instances, well-known structures and methods of semiconductor processing comprising embodiments of the subject matter disclosed herein have not been described in detail to avoid obscuring the descriptions of other aspects of the present disclosure.

Reference throughout the specification to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same aspect. Furthermore, the particular features, structures, or characteristics may be combined in any suitable manner in one or more aspects of the present disclosure.

The present disclosure is directed to various implementations of a transistor that incorporates amorphous metal thin films. Amorphous metal thin films, used in conjunction with an insulating layer perform transistor functions without the complexity of standard, silicon based transistors. Such amorphous metal transistors can be formed on any number of support substrates, giving flexibility to designers with regard to the types of materials and products that can incorporate transistors, i.e., active circuitry. These amorphous metal transistors can be formed on flexible substrate as they can bend and change shapes without damage to the circuitry. These flexible substrates may be polymers, glass or other materials.

Many aspects of our lives are benefited by utilizing ever smaller electronic devices. These include televisions, mobile electronic devices, like cellular phones, smart phones, tablet computers, and wearable electronics, like smart watches and pedometers. The transistors built on semiconductor substrates are limited by the materials used to form these circuits, i.e., silicon or other semiconductor wafers. With flexible transistors, the potential uses of electronic devices can be further expanded and improved, such as lighter and faster displays, wearable displays, mobile or easily movable displays, integrated into internet-of-things applications, or be integrated into medical devices.

These transistor structures can be used to form high-performance analog devices or digital devices as the end application dictates.

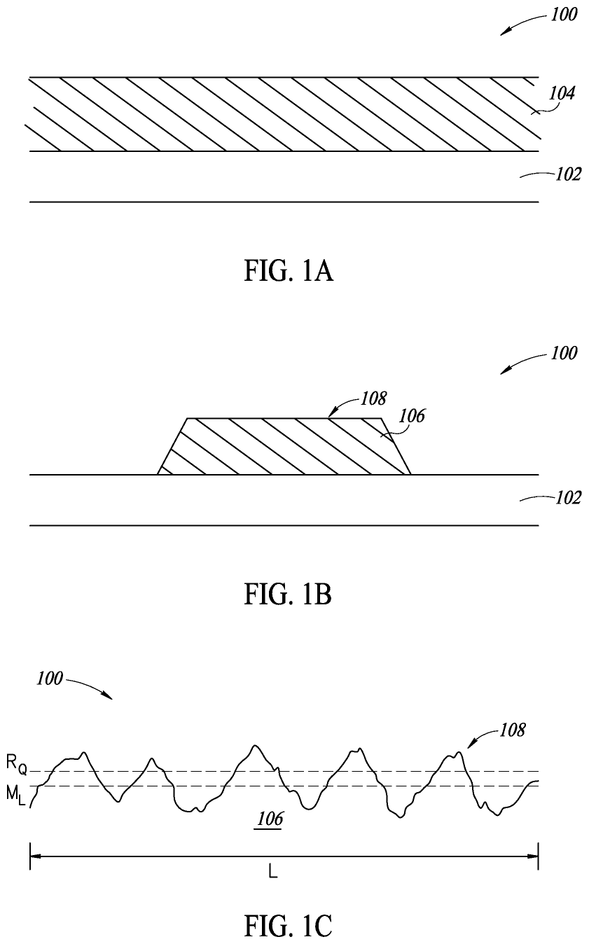

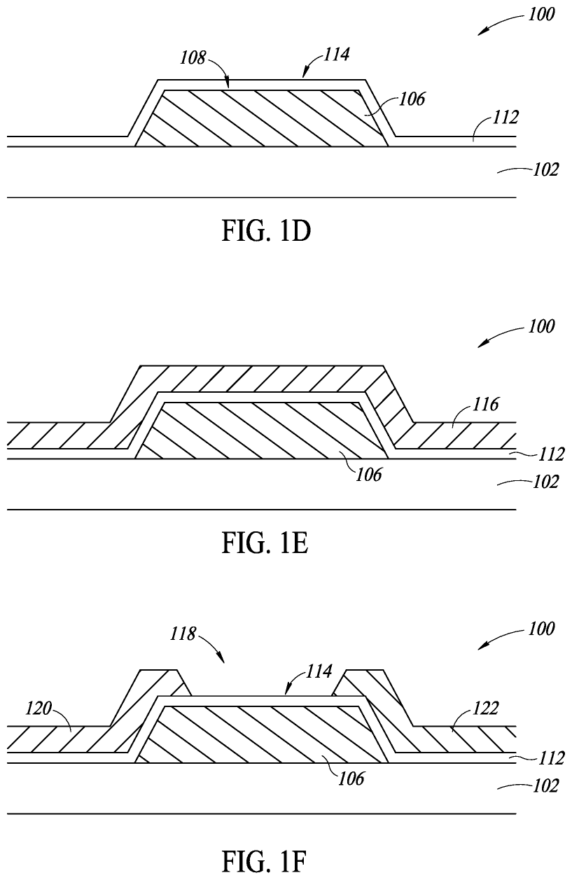

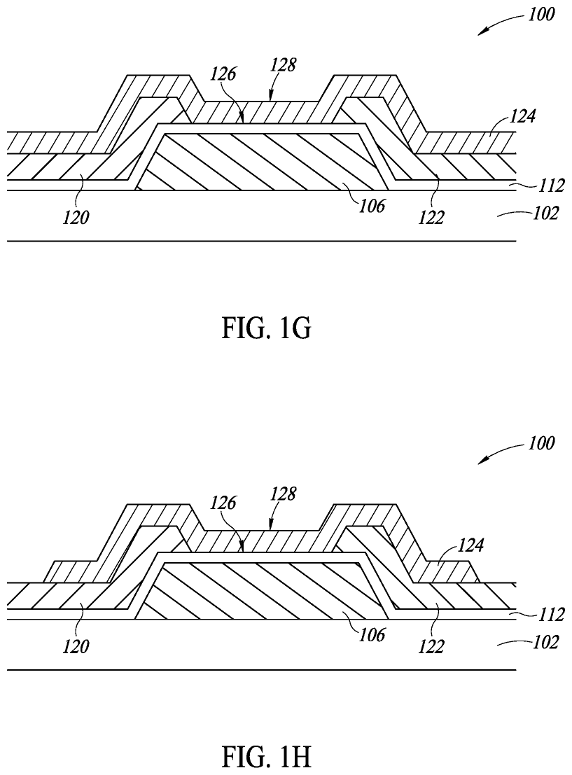

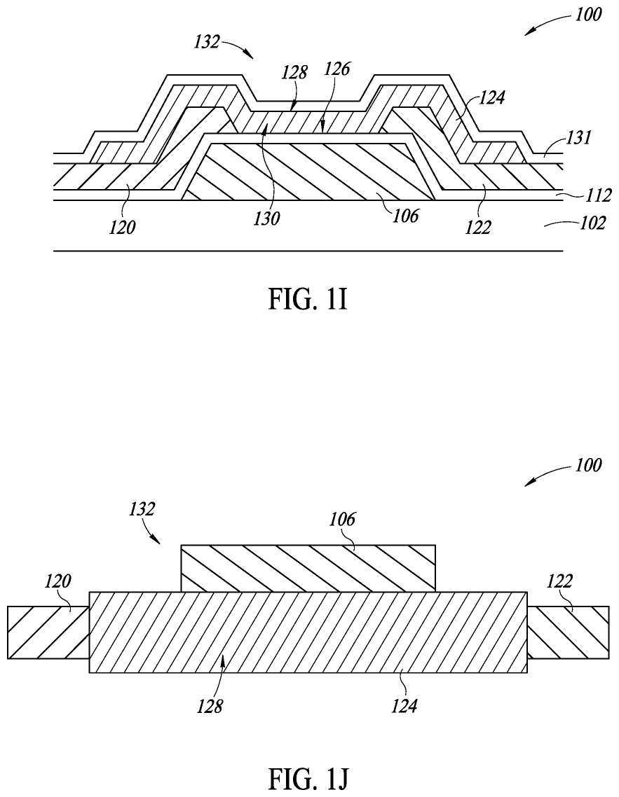

FIG. 1A is a cross-sectional view of a thin-film electronic device 100 and an intermediate stage of processing, according to one embodiment. The thin-film electronic device 100 includes a substrate 102. The substrate 102 corresponds to a support substrate on which a thin-film transistor will be formed. The thin-film transistor may include many materials and structures that are nontraditional with respect to traditional complimentary metal-oxide-semiconductor (CMOS) transistors. Accordingly, the substrate 102 may include nontraditional materials and characteristics with respect to CMOS transistors. For example, traditional CMOS transistors typically performed on a monocrystalline semiconductor substrate. However, the substrate 102 may include materials other than monocrystalline semiconductors, though monocrystalline semiconductors can be used in some embodiments. The ability to use materials other than monocrystalline semiconductors can greatly simplify the manufacturing process and reduce the manufacturing cost.

The substrate 102 can include a substantially nonconductive material. The substrate can be glass, a polymer, plastic, or other materials. In some embodiments, the substrate is glass, a polymer, plastic, or other material. In other embodiments, the substrate is a rubber. As used herein, “rubber” includes polymers of isoprene as well as forms of polyisoprene. In some such embodiments, the substrate is a plastic. Any suitable plastic may be used. In some embodiments, the plastic is a polyimide, an arylamide, acrylamide, polybenzimidazole (PBI), polyetherimide, polyetherketoneketone (PEKK), polyether ether ketone (PEEK), polyamide, polyimide, polyamide-imides, polystyrene (PS), polyphenylene oxide (PPO), polyphthalamide (PPA), polyvinyl alcohol (PVA), acrylonitrile butadiene styrene (ABS), polycarbonate (PC), thermoset, PBI-PEEK, urea, epoxies, polyurethanes, or any combination thereof. In some embodiments, the plastic is a polyethylene. In particular embodiments, the plastic is a high density polyethylene.

In further embodiments, the flexible substrate can be deformed (e.g., bowed, rolled, etc.) to form a curve having a central angle of at least about 5 degrees. In some embodiments, the flexible substrate can be deformed (e.g., bowed, rolled, etc.) to form a curve having a central angle of at least about 10 degrees. Unless otherwise specified, the central angle is measured for a curve in relation to an apex of the curve.

The materials of the support substrate can be selected by the manufacturer based on the end application of the transistor structure and the ultimate device being manufactured. For example, if the transistor structure is incorporated with an array of transistor structures, the array could be implemented within a liquid crystal display. Other end applications include wearable electronics. The support substrate can be transparent or non-transparent, such as those that can be used in some reflective displays.

Manufacturing on non-conducting flexible support substrates can reduce manufacturing costs significantly. Such substrates can enable roll-to-roll manufacturing of transistors. Such manufacturing changes can redefine the electronic supply chain.

The thin-film electronic device 100 includes a layer of conductive material 104 positioned on the substrate 102. The layer of conductive material 104 can include a crystalline material, a polycrystalline material, or an amorphous material, according to various embodiments. The layer of conductive material 104 can include a metal or other types of conductive materials. As will be described in greater detail with respect to FIGS. 1B and 1C, the layer of conductive material 104 has a smooth upper surface.

In one embodiment, the layer of conductive material 104 includes titanium aluminum. In particular, the layer of conductive material 104 can include TiAl₃. The thickness of the TiAl₃ is between 80 nm and 100 nm, though other thicknesses can be used without departing from the scope of the present disclosure. The TiAl₃ can have an amorphous structure. The TiAl₃ can be deposited with a physical vapor deposition (PVD) process. The PVD process can include sputtering, evaporation, or other PVD processes. The TiAl₃ has a roughness less than 1 nm.

In one embodiment, the layer of conductive material 104 includes titanium. The thickness of the titanium is between 80 nm and 100 nm, though other thicknesses can be used without departing from the scope of the present disclosure. The titanium can have a crystalline structure. The titanium can be deposited with a PVD process. The PVD process can include sputtering, evaporation, or other PVD processes. The titanium has a roughness less than 2 nm.

In one embodiment, the layer of conductive material 104 includes molybdenum. The thickness of the molybdenum is between 40 nm and 60 nm, though other thicknesses can be used without departing from the scope of the present disclosure. The molybdenum can have an amorphous structure. The molybdenum can be deposited with a PVD process. The PVD process can include sputtering, evaporation, or other PVD processes. The molybdenum has a roughness less than 2 nm.

In one embodiment, the layer of conductive material 104 includes copper. The thickness of the copper is between 15 nm and 35 nm, though other thicknesses can be used without departing from the scope of the present disclosure. The copper can have a crystalline structure. The copper can be deposited with an atomic layer deposition (ALD) process. The copper has a roughness less than 2 nm.

FIG. 1B is a cross-sectional view of the thin-film electronic device 100 and an intermediate stage of processing, according to one embodiment. In FIG. 1B, the layer of conductive material 104 has been patterned to form a gate electrode 106. The gate electrode can be formed from the layer of conductive material 104 by a photolithography process. The photolithography process can include patterning a mask on the layer of conductive material 104 and etching the layer of conductive material 104 in the presence of the mask. The etching process can include a wet etch or dry etch. The resulting gate electrode 106 has a shape corresponding to the shape of the mask.

The gate electrode 106 has a top surface 108. The roughness of the top surface 108 can affect the performance of the thin-film transistor in which the gate electrode 106 will be part. As will be set forth in more detail in subsequent figures, gate insulator and semiconductor materials will be formed above the gate electrode 106. The roughness of the top surface 108 of the gate electrode 106 influences the roughness of subsequent gate insulator and semiconductor layers. If the top surface 108 of the gate electrode 106 is rough, the top surface of the subsequent gate insulator and semiconductor layers may likewise be rough. If the top surface of the gate electrode 106 is smooth, the top surface of the subsequent gate insulator and semiconductor layers may likewise be smooth.

As will be described in more detail and subsequent figures, the smoothness of the top and bottom surfaces a semiconductor layer of a thin-film transistor can affect the performance of the thin-film transistor. Rougher top and bottom surfaces of a semiconductor layer can result in trap states that can trap charge carriers, such as electrons, and prevent them from transitioning across the bandgap from a valence band to a conduction band. While trap states can exist anywhere within a semiconductor material, trap states are much more likely to occur at rough surfaces of a semiconductor material. The more charge carriers that are trapped in trap states at the surfaces of the semiconductor layer, the lower the conductivity of the semiconductor layer. Low conductivity in the semiconductor layer may correspond to poor performance of the thin-film transistor.

Accordingly, as the roughness of the surfaces of the semiconductor layer is influenced by the roughness of the gate electrode 106, embodiments of the present disclosure provide a gate electrode 106 having a top surface 108 with low roughness. In one embodiment, the top surface 108 of the gate electrode 106 has a roughness less than 2 nm. Based on the material of the deposition process of the layer of conductive material 104, the top surface 108 of the gate electrode 106 may have a roughness less than 1 nm. For example, a gate electrode 106 of crystalline titanium may have a roughness of about 0.5 nm. A gate electrode 106 of amorphous TiAl₃ may have a roughness of about 0.2 nm.

Unless stated otherwise, as used herein, roughness values are given as root mean square (RMS) roughness values, though other types of roughness values can be used. For example, roughness can be given as the arithmetical mean deviation of an assessed surface profile, as a maximum valley depth of the assessed surface profile, the maximum peak height of the assessed surface profile, the skewness of the assessed surface profile, the kurtosis of the assessed surface profile, or the average distance between the highest peak and lowest valley in each sampling length. Those of skill in the art will recognize, in light of the present disclosure, that while RMS roughness is used herein, various other surface roughness assessments can be utilized without departing from the scope of the present disclosure.

FIG. 1C is an enlarged cross-sectional view of a portion of the top surface 108 of the gate electrode 106 of FIG. 1B, according to one embodiment. The view of FIG. 1C illustrates that the top surface 108 includes various peaks and valleys. The heights and depths of the peaks and valleys as shown in FIG. 1C may not correspond to an accurate representation of the top surface 108 of the gate electrode 106. However, the view of FIG. 1C is helpful in illustrating the principle of surface roughness and, in particular, RMS roughness.

In FIG. 1C, a mean line ML is illustrated. The mean line ML corresponds to the mean height of the top surface 108 when all peaks and valleys are taken into account along the sampling length L. Accordingly, the mean line ML is at a height between the highest peak and the lowest valley of the top surface 108 of the gate electrode 106.

The RMS roughness is represented by the line RQ in FIG. 1C. The RMS roughness RQ is calculated by taking a number of height measurement samples relative to the mean line ML. Heights that are greater than the mean line ML have a positive value. Heights that are lower than the mean line ML have a negative value. Each of the individual height measurements is squared. The squares of all the height measurements are summed and divided by the number of samples. The square root of this value is the RMS roughness RQ and has units of distance. Accordingly, and RMS roughness of 2 nm means that the line RQ is 2 nm above the mean line ML. A larger RMS roughness value indicates a rougher surface. Unless specified otherwise, roughness values provided herein correspond to RMS roughness values.

Materials, deposition processes, and etching processes for forming the gate electrode 106 are selected to provide a top surface 108 having a roughness less than 2 nm. In particular embodiments, the roughness may be less than 1 nm or less than 0.5 nm. Such low roughness values of the top surface 108 can promote subsequently deposited layers having similarly low roughness values.

With reference again to FIG. 1A, after deposition of the layer of conductive material 104, one or more planarization processes may be performed on the layer of conductive material 104. For example, a chemical mechanical planarization (CMP) process may be performed on the layer of conductive material 104. The CMP process utilizes chemical and mechanical polishing processes to reduce the roughness of the top surface of the layer of conductive material 104. This can result in the gate electrode 106 having a top surface 108 with low roughness.

With reference again to FIG. 1B, after patterning the conductive material 104 to form the gate electrode 106, one or more planarization processes may be performed on the gate electrode 106. For example, a CMP process may be performed on the gate electrode 106 to further reduce the roughness of the top surface 108 of the gate electrode 106.

The gate electrode 106 can be formed in ways other than those described above. For example, the gate electrode 106 can be formed by depositing the gate electrode metal in trench or gap formed in a dielectric layer formed on the substrate 102. This can be followed by a planarization process, such as a CMP process to remove excess metal and to reduce the roughness of the top surface 108 of the gate electrode 106.

FIG. 1D is a cross-sectional diagram of the thin-film electronic device 100 at an intermediate stage of processing, according to one embodiment. In FIG. 1D, a gate insulator 112 is formed on the top surface 108 of the gate electrode 106 and on exposed portions of the substrate 102. The gate insulator 112 has a material and thickness selected to enable the gate insulator 112 to electrically insulate the gate electrode 106 from a semiconductor channel region that will be deposited subsequently.

The gate insulator 112 can have a thickness between 5 nm and 25 nm. The inventors have found that such a relatively low thickness can result in a top surface 114 of the gate insulator 112 having a relatively low roughness. In particular, when the gate insulator 112 has a thickness less than 25 nm and is formed on a gate electrode 106 having a top surface 108 with a roughness less than 2 nm, the gate insulator 112 has a top surface 114 with a low roughness. In one example, the roughness of the top surface 114 of the gate insulator 112 is less than 2 nm. The low surface roughness of the top surface 114 of the gate insulator 112 can promote low surface roughness in a subsequently deposited semiconductor layer.

The gate insulator 112 can include AL₂O₃. The thickness and deposition process utilized for the gate insulator 112 can be selected based on the material and thickness of the gate electrode 106. The gate insulator 112 can be deposited by a PVD process, a CVD process, such as PECVD, or an ALD process. In an example in which the gate electrode 106 includes TiAl₃ with a thickness between 80 nm and 100 nm and a surface roughness less than 1 nm, the Al₂O₃ gate insulator 112 can be deposited with a PVD process. The thickness of the AL₂O₃ gate insulator 112 can be about 15 nm. In an example in which the gate electrode 106 includes Ti with a thickness between 80 and 100 nm and the surface roughness less than 2 nm, the AL₂O₃ gate insulator 112 can be deposited with a PVD process and have a thickness of about 15 nm. In an example in which the gate electrode 106 includes molybdenum with a thickness between 40 nm and 60 nm and a surface roughness less than 2 nm, the AL₂O₃ gate insulator 112 can be deposited with an ALD process and can have a thickness between 5 nm and 15 nm. In an example in which the gate electrode 106 includes copper with a thickness between 20 nm and 30 nm in the surface roughness less than 2 nm, the AL₂O₃ gate insulator 112 can be deposited with an ALD process and have a thickness between 3 nm and 8 nm. In an example in which the gate electrode includes titanium with a thickness between 20 nm and 30 nm in the surface roughness less than 2 nm, the gate AL₂O₃ insulator 112 can be deposited with a PVD process and can have a thickness between 5 nm and 15 nm.

The gate insulator 112 can include materials other than AL₂O₃. For example, the gate insulator 112 can include one or more of silicon oxide, silicon nitride, a metal oxide, hafnium oxide, etc. In embodiments, the gate insulator 112 insulator is a metal oxide or metal nitride that can be formed in a very thin layer. In some embodiments, portions of the gate insulator layer 112 between the source/drain electrodes and the gate electrode 106 may be thinner than other portions.

FIG. 1E is a cross-sectional view of the thin-film electronic device 100 at an intermediate stage of processing, according to one embodiment. In FIG. 1E, a layer of conductive material 116 is deposited on the gate insulator 112. The layer of conductive material 116 can have a thickness between 50 nm and 100 nm. The layer of conductive material 116 can include a metal. The metal can include one or more of copper, aluminum, titanium, tungsten, or other suitable metals. The layer of conductive material 116 can be deposited by PVD, chemical vapor deposition (CVD), ALD, or other suitable deposition processes.

FIG. 1F is a cross-sectional diagram of the thin-film electronic device 100 and an intermediate stage of processing, according to one embodiment. In FIG. 1F, an opening 118 has been formed in the layer of conductive material 116. The opening 118 exposes portion of the top surface 114 of the gate insulator 112. The opening 118 also defines a source electrode 120 and a drain electrode 122 from the layer of conductive material 116. The opening 118 can be formed by a photolithography process including forming a mask on the layer of conductive material 116 and etching exposed portions of the layer of conductive material 116 with a wet etch or a dry etch.

FIG. 1G is a cross-sectional view of the thin-film electronic device 100 at an intermediate stage of processing, according to one embodiment. In FIG. 1G, a semiconductor material 124 has been deposited on the source electrode 120, the drain electrode 122, and the exposed portion of the gate insulator 112. The semiconductor material 124 can have a thickness between 15 nm and 55 nm. The semiconductor material 124 can be formed with a deposition process including PVD, plasma enhanced CVD (PECVD), and PECVD with Excimer laser annealing (ELA).

The semiconductor material 124 can include one or more of IGZO (compositions of In, Ga, Zn, and O), low temperature polycrystalline silicon (LTPS), amorphous silicon, or other suitable semiconducting materials. In an example in which the gate insulator 112 includes AL₂O₃ between 10 nm and 20 nm in thickness, the semiconductor material 124 can include IGZO between 30 nm and 50 nm in thickness, formed with a PVD process. In an example in which the gate insulator 112 includes AL₂O₃ between 5 nm and 15 nm in thickness and the gate electrode 106 includes molybdenum, the semiconductor material 124 can include LTPS between 40 nm and 60 nm in thickness, formed with a PECVD process followed by an ELA process. In an example in which the gate insulator 112 includes AL₂O₃ between 3 nm and 8 nm in thickness, the semiconductor material 124 can include amorphous silicon between 40 nm and 60 nm in thickness, formed with a PECVD process. In an example in which the gate insulator 112 includes AL₂O₃ between 5 nm and 15 nm in thickness and the gate electrode 106 includes titanium, the semiconductor material 124 can include IGZO between 15 nm and 25 nm in thickness, formed with a PVD process followed by an ELA process. These embodiments can result in a semiconductor material 124 having a bottom surface 126 and a top surface 128 with relatively low roughness. Accordingly, the semiconductor material 124 can have a low number of trap states at the bottom and top surfaces 126, 128, and correspondingly high conductivity.

In some embodiments, IGZO may correspond to amorphous In—Ga—Zn—O compositions, also referred to as a-IGZO. In other embodiments, IGZO may include crystalline materials. Crystalline IGZO materials may include, for example, InGaZnO₄, InGaO₃(ZnO)₅, or In₂Ga₂ZnO₇. IGZO may also include In_{w}GaₓZn_{y}O_{z} in which w, x, y, and z are numbers that collectively sum to 1 and individually represent the proportion, by mass, of the material made up by the corresponding element. The values of w, x, y, and z can vary based on the deposition process. In one example, w=0.486, x=0.267, y=0.99, and z=0.148. Other values of w, x, y, and z can be utilized without departing from the scope of the present disclosure.

FIG. 1H is a cross-sectional view of the thin-film electronic device 100 at an intermediate stage of processing, according to one embodiment. In FIG. 1H, the semiconductor material 124 has been etched so that the semiconductor material 124 terminates on the source electrode 120 and the drain electrode 122. The semiconductor material 124 can be patterned and etched with photolithographic masking process followed by a wet or a dry etch.

FIG. 1I is a cross-sectional view of the thin-film electronic device 100 and an intermediate stage of processing, according to one embodiment. In FIG. 1I, a passivation layer 131 has been formed on the semiconductor material 124 and exposed portions of the source electrode 120 and drain electrode 122. The passivation layer 131 can include a dielectric material with a thickness between 50 nm and 500 nm. The passivation layer 131 can include one or more of silicon dioxide, silicon nitride, or other dielectric materials.

In FIG. 1I, the formation of a thin-film transistor 132 is complete. The thin-film transistor 132 includes the gate electrode 106, the gate insulator 112, the source electrode 120, the drain electrode 122, and the semiconductor material 124. The semiconductor material 124 includes a channel region 130. The channel region 130 corresponds to the portion of the semiconductor material 124 between the source and drain electrodes 120, 122 and the above the gate electrode 106. The gate insulator 112 separates the channel region 130 of the semiconductor material 124 from the gate electrode 106.

The thin-film transistor 132 can operate by selectively applying voltages to the gate electrode 106, the source electrode 120, and the drain electrode 122. In one example, thin-film transistor 132 is turned on by applying a gate to source voltage and a drain to source voltage of about 4V. The thin-film transistor 132 can be turned off by applying a gate to source voltage of 0 V. Other voltages can be utilized without departing from the scope of the present disclosure.

FIG. 1J is a top view of the thin-film transistor 132 of FIG. 1I. The gate insulator 112 and the passivation layer 131 are not shown. FIG. 1J illustrates that the semiconductor material 124 is positioned over portions of the gate electrode 106, the source electrode 120, and the drain electrode 122. The various components of the thin-film transistor 132 can have other shapes and arrangements without departing from the scope of the present disclosure.

While the description of FIGS. 1A-1J has primarily described formation of a thin film transistor 132 including a gate electrode 106 having a top surface 108 with low roughness, principles of the present disclosure can extend to other structures formed in the thin-film electronic device 100. For example, the layer of conductive material 104 can be patterned to form various types of metal structures on the substrate 102 in addition to the gate electrode 106. These other metal structures will also have top surfaces with the low roughness of the top surface 108. Accordingly, these other metal structures, and the structures formed over them, may also benefit from the low roughness top surface. The other metal structures can include metal lines, contacts, plugs, or types of metal structures that may be formed with the metal of the gate electrode 106.

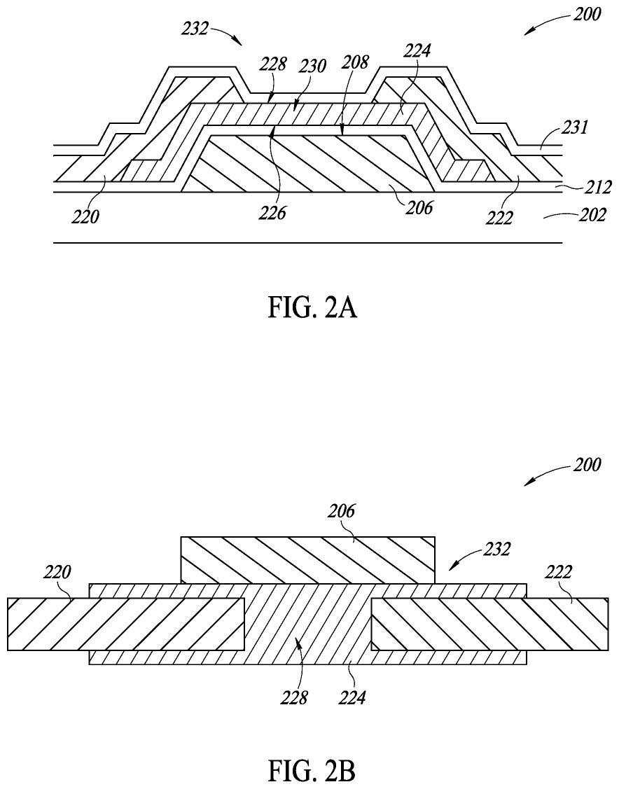

FIG. 2A is a cross-sectional view of a thin-film electronic device 200 including a thin-film transistor 232, according to one embodiment. The transistor 232 includes a gate electrode 206 positioned on a substrate 202. The gate insulator 212 is positioned on the gate electrode 206 and the substrate 202. A semiconductor material 224 is positioned on the gate insulator 212. A source electrode 220 and the drain electrode 222 are positioned on the semiconductor material 224. A passivation layer is positioned on the source electrode 220, the drain electrode 222, and the semiconductor material 224. Accordingly, the thin-film transistor 232 of FIG. 2A is substantially similar to the thin-film transistor 132 of FIG. 1I, except that the source and drain electrodes 220, 222 are formed after formation of the semiconductor material 224. The various components of the thin-film transistor 232 can be formed with the same processes, dimensions, and materials as described previously in relation to FIGS. 1A-30 1J.

The gate electrode 206 has surface roughness characteristics as described in relation to the gate electrode 106 of FIG. 1A-1J. This results in the semiconductor material 224 having bottom surface 226 and top surface 228 with low roughness like the semiconductor material 124 of FIG. 1I. Accordingly, although the order of deposition of some of the components of the thin-film transistor 232 is different than the order of deposition of some of the components of the thin-film transistor 132, the thin-film transistor 232 has the same beneficial low surface roughness characteristics as the thin-film transistor 132.

FIG. 2B is a top view of the thin-film transistor 232 of FIG. 2A. The top view of the thin-film transistor 232 illustrates that the source electrode 220 and the drain electrode 222 are positioned on the semiconductor material 224. The semiconductor material 224 is positioned over the gate electrode 206.

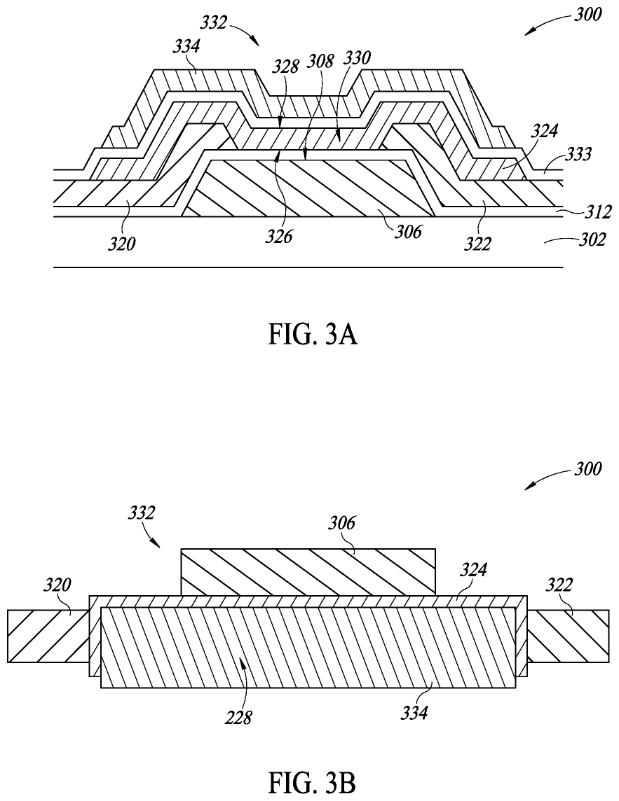

FIG. 3A is a cross-sectional view of a thin-film electronic device 300 including a thin-film transistor 332, according to one embodiment. The thin-film transistor 332 includes a substrate 302, a gate electrode 306 positioned on the substrate 302, a gate insulator 312 positioned on the gate electrode 306 and substrate 302, source and drain electrodes 320, 322 positioned on the gate insulator 312, and a semiconductor material 324 positioned on the source electrode 320, the drain electrode 322, and the gate insulator 312. These components of the thin-film transistor 332 can be formed with the same processes, materials, and thicknesses described for the thin-film transistor 132 in relation to FIGS. 1A-1J. The thin-film transistor 332 is substantially similar to the thin-film transistor 132 of FIG. 1I, except that a second gate insulator 333 is positioned on the semiconductor material 324 and a second gate electrode 334 is positioned on the second gate insulator 333. The second gate insulator 333 can be of the same material and thickness as the gate insulator 312. The second gate electrode 334 can have a same material and thickness as the gate electrode 306. Control of currents in the channel region 330 can be enhanced by applying the same voltages to the second gate electrode 334 as are applied to the first gate electrode 306. Though not shown in FIG. 3A, a passivation layer, similar to the passivation layer 131, can be deposited on the thin-film transistor 332. In the example of FIG. 3A, gate electrode 306 can be considered a first gate electrode.

The gate electrode 306 has surface roughness characteristics as described in relation to the gate electrode 106 of FIG. 1A-1J. This results in the semiconductor material 324 having bottom surface 326 and top surface 328 with low roughness like the semiconductor material 124 of FIG. 1I. Accordingly, although the order of deposition of some of the components of the thin-film transistor 332 is different than the order of deposition of some of the components of the thin-film transistor 132, the thin-film transistor 332 has the same beneficial low surface roughness characteristics as the thin-film transistor 132.

The thin-film transistor 332 will include contacts or other electrical connections through the second gate insulator 333 to the source and drain electrodes 320, 322. These contacts are in openings formed in the second gate insulator 333, which are not shown in FIG. 3A. The contacts may be formed in a same processing step as the second gate electrode 334 such that they are formed from the same layer, but are electrically isolated from each other.

FIG. 3B is a top view of the thin-film transistor 332 of FIG. 3A. The top view of the thin-film transistor 332 illustrates that the second gate electrode 334 is positioned over the semiconductor material 324. The semiconductor material 324 is positioned over the source and drain electrodes 320, 322 and the gate electrode 306.

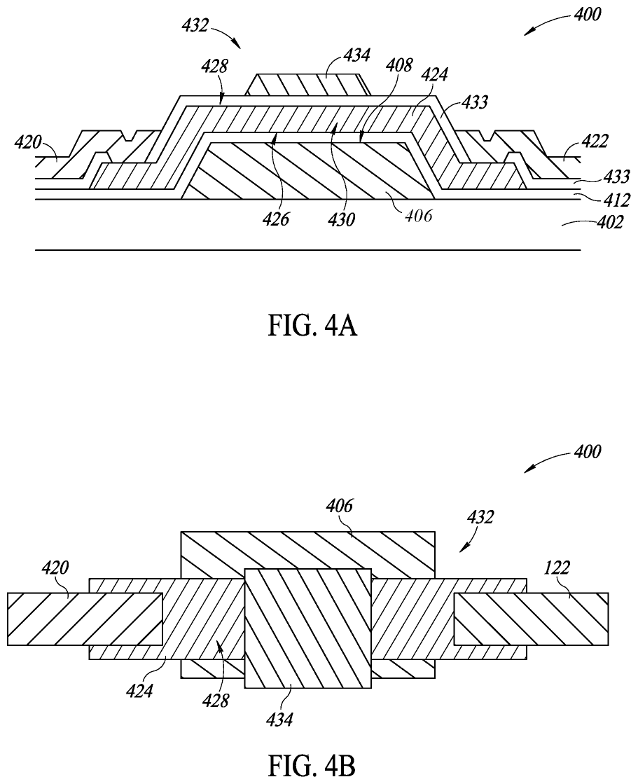

FIG. 4A is a cross-sectional view of a thin-film electronic device 400 including a thin-film transistor 432, according to one embodiment. The thin-film transistor 432 includes a substrate 402, a gate electrode 406 positioned on the substrate 402, a gate insulator 412 positioned on the gate electrode 406 and substrate 402, source and drain electrodes 420, 422 positioned on the gate insulator 412, and a semiconductor material 424 positioned on the source electrode 420, the drain electrode 422, and the gate insulator 412. These components of the thin-film transistor 432 can be formed with the same processes, materials, and thicknesses described for the thin-film transistor 132 in relation to FIGS. 1A-1J. The thin-film transistor 432 is substantially similar to the thin-film transistor 132 of FIG. 1I, except that a second gate insulator 433 is positioned on the semiconductor material 424 and a second gate electrode 434 is positioned on the second gate insulator 433. The second gate insulator 433 can be of the same material and thickness as the gate insulator 412. The second gate electrode 434 can have a same material and thickness as the gate electrode 406. Control of currents in the channel region 430 can be enhanced by applying the same voltages to the second gate electrode 434 as are applied to the first gate electrode 406. Though not shown in FIG. 4A, a passivation layer, similar to the passivation layer 131, can be deposited on the thin-film transistor 432. In the example of FIG. 4A, the gate electrode 406 can be considered a first gate electrode.

The gate electrode 406 has surface roughness characteristics as described in relation to the gate electrode 106 of FIG. 1A-1J. This results in the semiconductor material 424 having bottom surface 426 and top surface 428 with low roughness like the semiconductor material 124 of FIG. 1I. Accordingly, although the order of deposition of some of the components of the thin-film transistor 432 is different than the order of deposition of some of the components of the thin-film transistor 132, the thin-film transistor 432 has the same beneficial low surface roughness characteristics as the thin-film transistor 132.

FIG. 4B is a top view of the thin-film transistor 432 of FIG. 4A. The top view of the thin-film transistor 432 illustrates that the second gate electrode 434 is positioned over the semiconductor material 424. The source and drain electrodes 420, 422 are positioned over the semiconductor material 424. The semiconductor material 424 is positioned over the gate electrode 406.

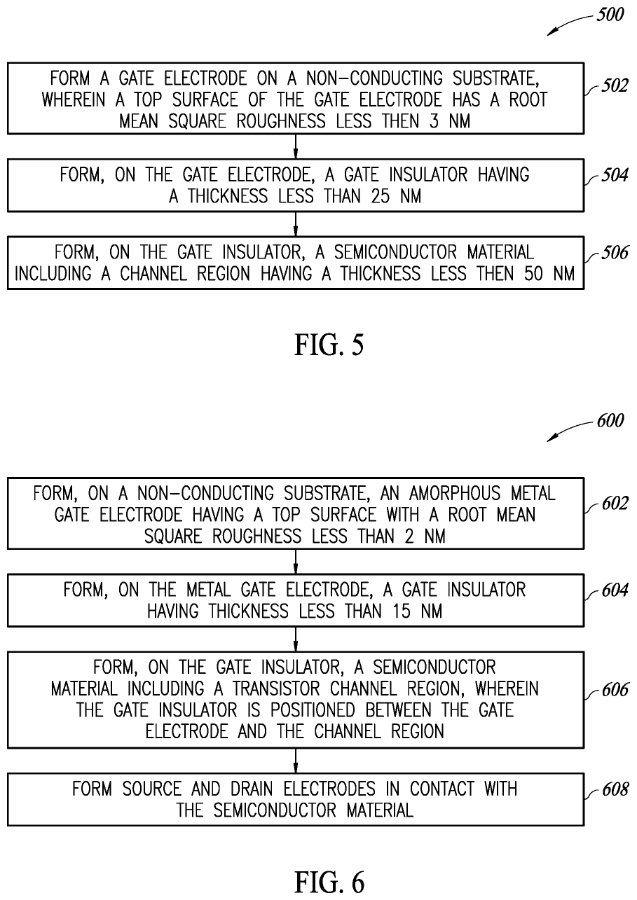

FIG. 5 is a flow diagram of a method 500 for forming a thin-film transistor, according to one embodiment. At 502, the method 500 includes forming a gate electrode on a non-conducting substrate, wherein a top surface of the gate electrode is the root mean square roughness less than 3 nm. At 504, the method 500 includes forming, on the gate electrode, the gate insulator having a thickness less than 25 nm. At 506, the method 500 includes forming, on the gate insulator, a semiconductor material including a channel region having a thickness less than 50 nm.

FIG. 6 is a flow diagram of a method 600 for forming a thin-film transistor, according to one embodiment. At 602, the method 600 includes forming, on a non-conducting substrate, an amorphous metal gate electrode having a top surface of the root mean square roughness less than 2 nm. At 604, the method 600 includes forming, on the metal gate electrode, a gate insulator having a thickness less than 15 nm. At 606, the method 600 includes forming, on the gate insulator, the semiconductor material including a transistor channel region, wherein the gate insulator is positioned between the gate electrode and the channel region. At 608, the method 600 includes forming source and drain electrodes in contact with the semiconductor material.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a non-conducting substrate;
a gate electrode positioned on the substrate and having top surface with a root mean square roughness less than 3 nm;
a gate insulator positioned on the gate electrode and having a thickness less than 25 nm; and
a semiconductor material positioned on the gate insulator and having a thickness less than 50 nm.

2. The device of claim 1, wherein the surface roughness of the top surface of the gate electrode is less than 2 nm.

3. The device of claim 2, wherein the surface roughness of the top surface of the gate electrode is less than 1 nm.

4. The device of claim 1, wherein the gate electrode includes an amorphous metal.

5. The device of claim 4, wherein the gate electrode includes titanium aluminide (TiAl₃).

6. The device of claim 1, wherein the gate electrode includes a crystalline material.

7-9. (canceled)

10. The device of claim 1, wherein the gate electrode has a thickness less than 90 nm.

11. The device of claim 10, wherein the gate electrode has a thickness less than 25 nm and the gate insulator has a thickness less than 15 nm.

12-13. (canceled)

14. The device of claim 1, wherein the gate insulator includes aluminum oxide (Al₂O₃).

15. (canceled)

16. The device of claim 1, wherein the semiconductor material includes a channel region, wherein the gate insulator is positioned between the channel region and the gate electrode.

17. The device of claim 16, wherein the channel region has a thickness less than 50 nm.

18. (canceled)

19. The device of claim 16, wherein the semiconductor material includes InGaZnO indium gallium zinc oxide (IGZO).

20. (canceled)

21. The device of claim 16, wherein the semiconductor material includes amorphous silicon.

22. The device of claim 16, further comprising:
a source electrode in contact with the semiconductor material; and
a drain electrode in contact with the semiconductor material.

23. The device of claim 22, wherein the source and drain electrodes are positioned above the semiconductor material.

24. The device of claim 23, wherein the source and drain electrodes are positioned below the semiconductor material.

25-27. (canceled)

28. A method, comprising:
forming a gate electrode on a non-conducting substrate, wherein a top surface of the gate electrode has a root mean square roughness less than 3 nm;
forming, on the gate electrode, a gate insulator having a thickness less than 25 nm; and
forming, on the gate insulator, a semiconductor material including a channel region having a thickness less than 50 nm.

29-34. (canceled)

35. The method of claim 28, wherein forming the semiconductor material includes performing an excimer laser annealing process.

36. The method of claim 28, wherein forming the semiconductor material includes performing a plasma enhanced chemical vapor deposition process.

37. The method of claim 28, further comprising forming source and drain electrodes in contact with the semiconductor material.

38. A method, comprising:
forming, on a non-conducting substrate, an amorphous metal gate electrode having a top surface with a root mean square roughness less than 2 nm;
forming, on the metal gate electrode, a gate insulator having a thickness less than 15 nm;
forming, on the gate insulator, a semiconductor material including a transistor channel region, wherein the gate insulator is positioned between the gate electrode and the channel region; and
forming source and drain electrodes in contact with the semiconductor material.

39. The method of claim 38, wherein the gate electrode includes indium tin oxide (ITO).

40. The method of claim 39, wherein the gate insulator includes aluminum oxide (Al₂O₃).
